(19) United States
(12) Patent Application Publication
(10) Pub. No.: US 2005/0189140 A1
(43) Pub. Date: Sep. 1, 2005

(54) Chip package structure

(76) Inventor: Chao-Ming Tseng, Qiaotou Shiang (TW)

Correspondence Address: J C PATENTS, INC., 4 VENTURE, SUITE 250, IRVINE, CA, 92618, US

(21) Appl. No.: 11/033,065

(22) Filed: Jan. 10, 2005

(30) Foreign Application Priority Data
Feb. 26, 2004 (TW) 93104888

(51) Int. Cl. H01L 23/495; H05K 1/16

(52) U.S. Cl. 174/260; 257/666

(57) ABSTRACT

A chip package structure including a substrate, a first chip, a second chip, a third chip and an encapsulant is provided. The substrate has a cavity, a plurality of first contacts and second contacts disposed on a surface thereof, wherein the first contacts are located within the cavity and the second contacts are located outside the cavity, the substrate further includes a through hole located at the bottom of the cavity. The first chip is disposed in the cavity and is electrically connected to the first contacts. The second chip is disposed above the cavity and is electrically connected to the second contacts. The third chip is disposed in the through hole and is attached to the first chip. The encapsulant is filled in the cavity to encapsulate the first chip and the second chip. Moreover, the second chip, the third chip or the through hole is optional.

### CROSS-REFERENCE TO RELATED APPLICATION

This application claims the priority benefit of Taiwan application serial no. 93104888, filed on Feb. 26, 2004.

### BACKGROUND OF THE INVENTION

1. Field of Invention

The present invention relates to a chip package structure. More particularly, the present invention relates to a stacked chip package structure having a smaller thickness.

2. Description of Related Art

As electronic technology progresses, the miniaturization of electronic products is increasingly emphasized. This miniaturization results in a more complicated and denser structure of electronic products. Accordingly, in the electronic industries, the packaging of electronic devices requires package structures to be small in dimensions and high in density. Therefore, multi-chip package is proposed for accommodating the miniaturization of the IC dimension and the enhancement of electrical performance.

FIG. 1 is a schematic cross-sectional view of a conventional stacked chip package structure. Referring to FIG. 1, the conventional stacked chip package structure 100 includes a substrate 110, a first chip 120, a second chip 130, a plurality of first wires 142, a plurality of second wires 144, a plurality of solder balls 146 and an encapsulant 150. The first chip 120 is disposed on the substrate 110 and is electrically connected to the substrate 110 through the first wires 142. The second chip 130 is disposed above the first chip 120 and is electrically connected to the substrate 110 through the second wires 144. The solder balls 146 are disposed on a rear surface of the substrate 110 such that the stacked chip package structure 100 can further connect to external carriers. The encapsulant 150 encapsulates the first chip 120, the second chip 130, the first wires 142 and the second wires 144.

As described above, the thickness of the stacked chip package structure 100 is determined by the thickness of the first chip 120 and the second chip 130, height of the second wires 144 and a predetermined thickness for laser marking. Therefore, the thickness of the stacked chip package structure 100 is hard to reduce. Moreover, to prevent the short circuit between the first wires 142 and the second wires 144, the length and the height of the first wires 142 are larger than those of the second wires 144. Thus, the electrical performance of the stacked chip package structure 100 deteriorates because of the first wires 142 and the dimension of the stacked chip package structure 100 is increased.

In addition, the wire-bonding process can't be performed on the first chip 120 when the size of the first chip 120 approximates to that of the second chip 130. To solve the problem described above, another stacked chip package structure is provided.

FIG. 2 is another schematic cross-sectional view of a conventional stacked chip package structure. Referring to FIG. 2, a spacer 160 is disposed between the first chip 120 and the second chip 130 of the conventional stacked chip package structure 100a. Other elements are similar to the stacked chip package structure 100 shown in FIG. 1, and the description thereof is omitted. Since the spacer 160 is disposed between the first chip 120 and the second chip 130, sufficient space is formed above the first chip 120 to perform a wire-bonding process such that the first chip 120 is electrically connected to the substrate 110 through the first wire 142. However, the thickness of the stacked chip package structure 100a is further increased due to the spacer 160. In other words, the thickness of the stacked chip package structure 1 00a is not reduced, and the disadvantages of the stacked chip package structure 100 also present in the stacked chip package structure 100a.

### SUMMARY OF THE INVENTION

The invention provides a chip package structure, wherein the dimension and the thickness of the chip package structure can be reduced.

The invention provides a chip package structure with better heat dissipation characteristic.

The invention provides a chip package structure with enhanced electrical performance.

As embodied and broadly described herein, the invention provides a chip package structure. The chip package structure comprises a substrate, a first chip, a second chip and an encapsulant. The substrate has a cavity. The substrate comprises a plurality of first contacts and second contacts disposed on a surface thereof, wherein the first contacts are located within the cavity and the second contacts are located outside the cavity. The first chip is disposed in the cavity and is electrically connected to the first contacts. The second chip is disposed above the cavity and is electrically connected to the second contacts. The encapsulant is filled in the cavity to encapsulate the first chip and the second chip.

In an embodiment of the present invention, the chip package structure further comprises a plurality of first bumps, wherein the first chip is electrically connected to the first contacts through the first bumps.

In an embodiment of the present invention, the chip package structure further comprises a plurality of second bumps, wherein the second chip is electrically connected to the second contacts through the second bumps.

In an embodiment of the present invention, the chip package structure further comprises a plurality of first wires, wherein the first chip is electrically connected to the first contacts through the first wires.

In an embodiment of the present invention, the chip package structure further comprises a plurality of second wires, wherein the second chip is electrically connected to the second contacts through the second wires.

In an embodiment of the present invention, the chip package structure further comprises a plurality of solder balls disposed on a rear surface of the substrate.

As embodied and broadly described herein, the invention provides another chip package structure. The chip package structure comprises a substrate, a first chip, a second chip, a third chip and an encapsulant. The substrate has a cavity. The substrate comprises a plurality of first contacts and second contacts disposed on a surface thereof, wherein the first contacts are located within the cavity and the second contacts are located outside the cavity. Moreover, the substrate further comprises a through hole located at the bottom of the cavity. The first chip is disposed in the cavity and is electrically connected to the first contacts. The second chip is disposed above the cavity and is electrically connected to the second contacts. The third chip is disposed in the through hole and is attached to the first chip. The encapsulant is filled in the cavity to encapsulate the first chip and the second chip.

In an embodiment of the present invention, the chip package structure further comprises a plurality of first bumps, wherein the first chip is electrically connected to the first contacts through the first bumps.

In an embodiment of the present invention, the chip package structure further comprises a plurality of second bumps, wherein the second chip is electrically connected to the second contacts through the second bumps.

In an embodiment of the present invention, the chip package structure further comprises a plurality of first wires, wherein the first chip is electrically connected to the first contacts through the first wires.

In an embodiment of the present invention, the chip package structure further comprises a plurality of second wires, wherein the second chip is electrically connected to the second contacts through the second wires.

In an embodiment of the present invention, the chip package structure further comprises a plurality of third bumps disposed on a surface of the third chip away from the first chip, and a plurality of solder balls disposed on a rear surface of the substrate.

In an embodiment of the present invention, the chip package structure further comprises a tape or an adhesive disposed between the third chip and the first chip.

As embodied and broadly described herein, the invention provides another chip package structure. The chip package structure comprises a substrate, a first chip, a second chip and an encapsulant. The substrate has a cavity. The substrate comprises a plurality of contacts disposed on a surface thereof, wherein the contacts are located within the cavity. Moreover, the substrate further comprises a through hole located at the bottom of the cavity. The first chip is disposed in the cavity and is electrically connected to the contacts. The second chip is disposed in the through hole and is attached to the first chip. The encapsulant is filled in the cavity to encapsulate the first chip.

In an embodiment of the present invention, the chip package structure further comprises a plurality of first bumps, wherein the first chip is electrically connected to the contacts through the first bumps.

In an embodiment of the present invention, the chip package structure further comprises a plurality of wires, wherein the first chip is electrically connected to the contacts through the wires.

In an embodiment of the present invention, the chip package structure further comprises a plurality of second bumps disposed on a surface of the second chip away from the first chip, and a plurality of solder balls disposed on a rear surface of the substrate.

In an embodiment of the present invention, the chip package structure further comprises a tape or an adhesive disposed between the second chip and the first chip.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional stacked chip package structure.

FIG. 2 is another schematic cross-sectional view of a conventional stacked chip package structure.

FIG. 3A˜FIG. 3D are schematic cross-sectional views of the chip package structure according to the first embodiment of the present invention.

FIG. 4A˜FIG. 4D are schematic cross-sectional views of the chip package structure according to the second embodiment of the present invention.

FIG. 5A and FIG. 5B are schematic cross-sectional views of the chip package structure according to the third embodiment of the present invention.

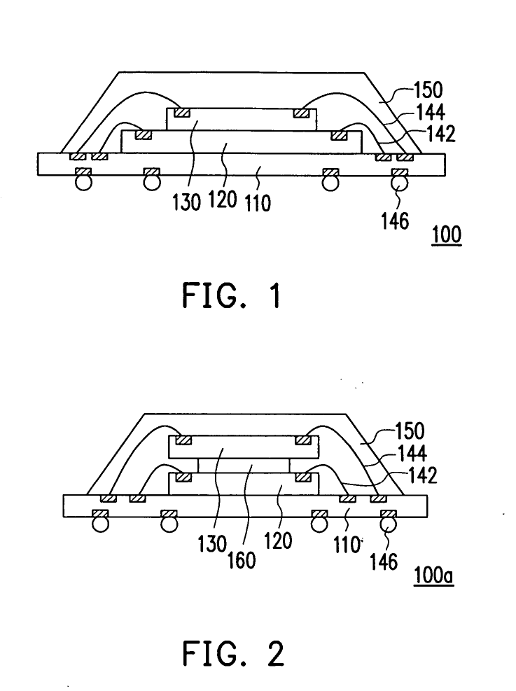

### DESCRIPTION OF THE PREFERRED EMBODIMENTS

### First Embodiment

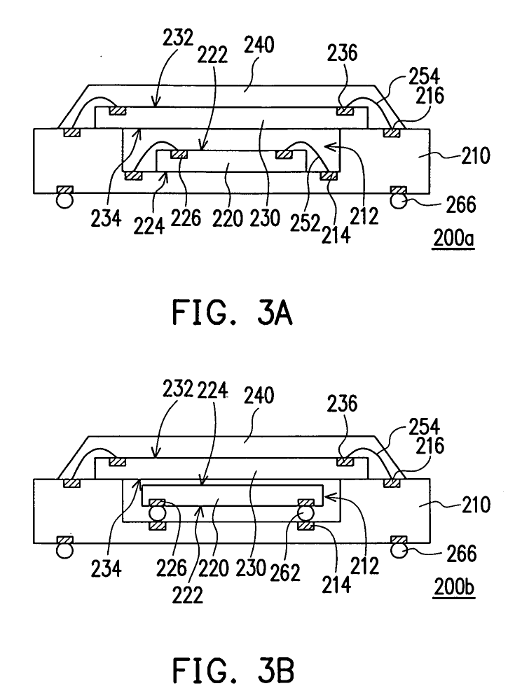

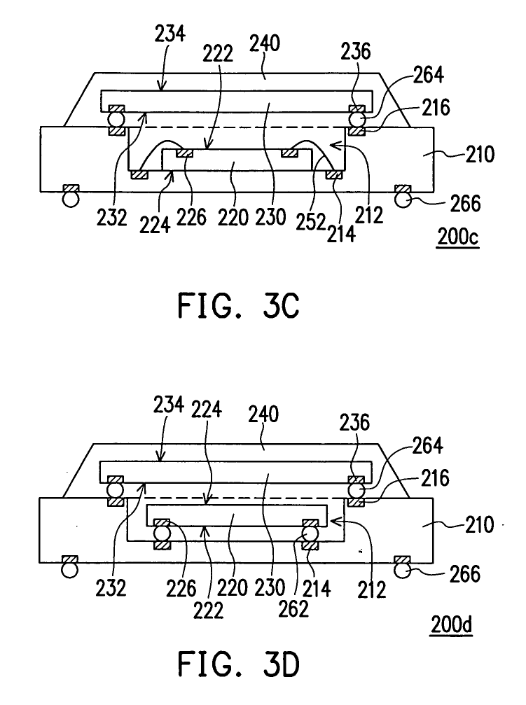

FIG. 3A˜FIG. 3D are schematic cross-sectional views of the chip package structure according to the first embodiment of the present invention. Referring to FIG. 3A˜FIG. 3D, the chip package structure 200a, 200b, 200c, 200d comprises a substrate 210, a first chip 220, a second chip 230 and an encapsulant 240. The substrate 210 has a cavity 212. The substrate 210 comprises a plurality of first contacts 214 and second contacts 216 disposed on a surface thereof, wherein the first contacts 214 are located within the cavity 212 and the second contacts 216 are located outside the cavity 212. The first chip 220 is disposed in the cavity 212 and is electrically connected to the first contacts 214. The second chip 230 is disposed above the cavity 212 and is electrically connected to the second contacts 216. The encapsulant 240 is filled in the cavity 212 to encapsulate the first chip 220 and the second chip 230. The encapsulant 240 protects the first chip 220 and the second chip 230 from damage resulted from moisture or shear stress so as to ensure electrical connection between chips and substrate 210. Moreover, the chip package structure 200a, 200b, 200c, 200d further comprises a plurality of solder balls 266 disposed on a rear surface of the substrate 210. The solder balls 266 are utilized for sequential electrical connection.

Referring to FIG. 3A and FIG. 3C, the chip package 200a, 200c further comprises a plurality of first wires 252. The first chip 220 has a first active surface 222 and a first back surface 224. The first chip 220 comprises a plurality of first bonding pads 226 disposed on peripheral area of the first active surface 222. The first chip 220 is disposed on the substrate 210 with the first back surface 224 in contact with the bottom of the cavity 212, wherein the first bonding pads 226 are electrically connected to the first contact 214 through the first wires 252 correspondingly.

Referring to FIG. 3A and FIG. 3B, the chip package 200a, 200b further comprises a plurality of second wires 254. The second chip 230 has a second active surface 232 and a second back surface 234. The second chip 230 comprises a plurality of second bonding pads 236 disposed on peripheral area of the second active surface 232. The second chip 230 is disposed above the substrate 210 with the second back surface 234 in contact with the top of the cavity 212, wherein the second bonding pads 236 are electrically connected to the second contact 216 through the second wires 254 correspondingly.

Referring to FIG. 3B and FIG. 3D, the chip package 200b, 200d further comprises a plurality of first bumps 262. The first chip 220 has a first active surface 222 and a first back surface 224. The first chip 220 comprises a plurality of first bonding pads 226 disposed on peripheral area of the first active surface 222. The first chip 220 is disposed on the substrate 210 with the first active surface 222 facing the bottom of the cavity 212, wherein the first bonding pads 226 are electrically connected to the first contact 214 through the first bumps 262 correspondingly.

Referring to FIG. 3C and FIG. 3D, the chip package 200a, 200b further comprises a plurality of second bumps 264. The second chip 230 has a second active surface 232 and a second back surface 234. The second chip 230 comprises a plurality of second bonding pads 236 disposed on peripheral area of the second active surface 232. The second chip 230 is disposed above the substrate 210 with the second active surface 232 facing the bottom of the cavity 212, wherein the second bonding pads 236 are electrically connected to the second contact 216 through the second bumps 264 correspondingly.

### Second Embodiment

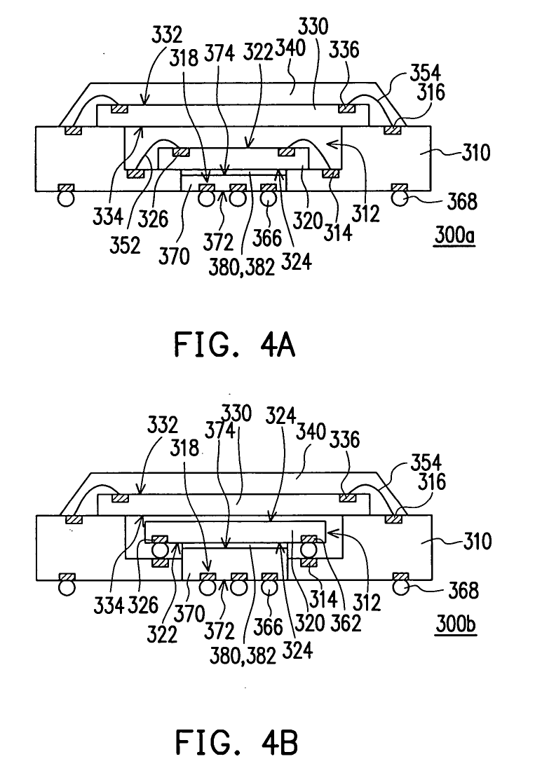

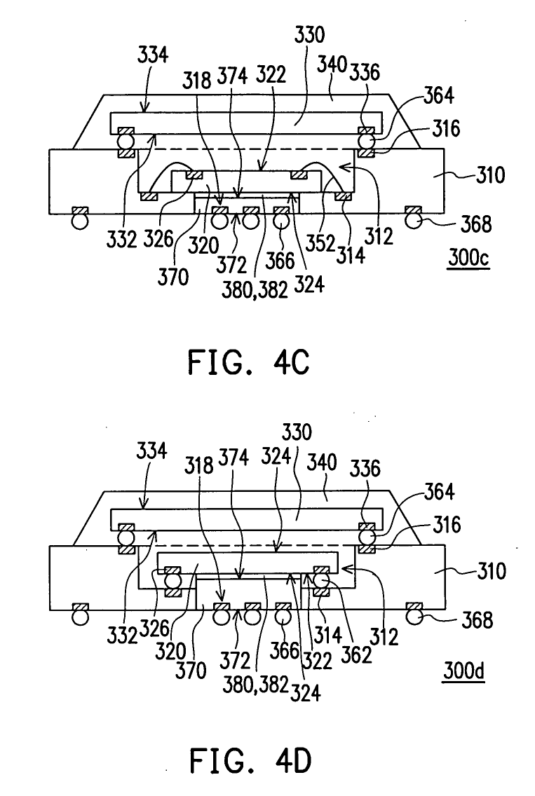

FIG. 4A˜FIG. 4D are schematic cross-sectional views of the chip package structure according to the first embodiment of the present invention. Referring to FIG. 4A˜FIG. 4D, the chip package structure 300a, 300b, 300c, 300d comprises a substrate 310, a first chip 320, a second chip 330, a third chip 370 and an encapsulant 340. The substrate 310 has a cavity 312. The substrate comprises a plurality of first contacts 314 and second contacts 316 disposed on a surface thereof, wherein the first contacts 314 are located within the cavity 312 and the second contacts 316 are located outside the cavity 312. Moreover, the substrate 310 further comprises a through hole 318 located at the bottom of the cavity 312. The first chip 320 is disposed in the cavity 312 and is electrically connected to the first contacts 314. The second chip 330 is disposed above the cavity 312 and is electrically connected to the second contacts 316. The third chip 370 has a third active surface 372 and a third back surface 374. The third chip 370 is disposed in the through hole 318 and is attached to the first chip 320. The encapsulant 340 is filled in the cavity 312 to encapsulate the first chip 320 and the second chip 330. In addition, the chip package structure 300a, 300b, 300c, 300d further comprises a plurality of third bumps 366 disposed on the third active surface 372 of the third chip 370. The chip package structure 300a, 300b, 300c, 300d further comprise a plurality of solder balls 368 disposed on a rear surface of the substrate 310.

In an embodiment of the present invention, a protect layer (not shown) is formed on the third active surface 372 of the third chip 370 to prevent from damage.

In the chip package structure 300a, 300b, 300c, 300d, the electrical connection between the first chip 320, the second chip 330 and the substrate 310 is the same with the electrical connection between the first chip 220, the second chip 230 and the substrate 210 (shown in FIG. 3A˜3D).

In an embodiment of the present invention, the chip package structure 300a, 300b, 300c, 300d further comprises a tape 380 disposed between the third chip 370 and the first chip 320. However, the tape 380 can be replaced by an adhesive 382. In other words, the third chip 370 and the first chip 320 are adhered with each other by a solid adhesive or a liquid adhesive to ensure connection between the third chip 370 and the first chip 320.

### Third Embodiment

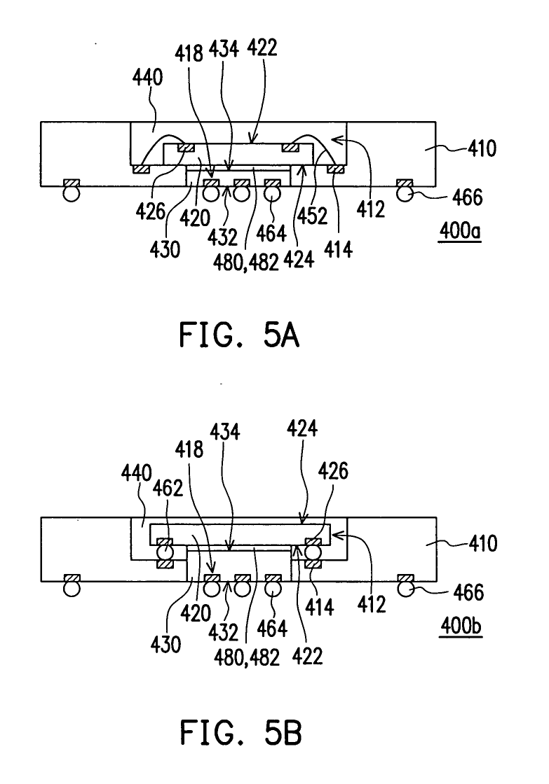

FIG. 5A and FIG. 5B are schematic cross-sectional views of the chip package structure according to the first embodiment of the present invention. Referring to FIG. 5A and FIG. 5B, the chip package structure 400a, 400b comprises a substrate 410, a first chip 420, a second chip 430 and an encapsulant 440. The substrate 410 has a cavity 412. The substrate 410 comprises a plurality of contacts 414 disposed on a surface thereof, wherein the contacts 414 are located within the cavity 412. Moreover, the substrate 410 further comprises a through hole 418 located at the bottom of the cavity 412. The first chip 420 is disposed in the cavity 412 and is electrically connected to the contacts 414. The second chip 430 has a second active surface 432 and a second back surface 434. The second chip 430 is disposed in the through hole 418 and the second back surface 434 is attached to the first chip 420. The encapsulant 440 is filled in the cavity 412 to encapsulate the first chip 420. In addition, the chip package structure 400a, 400b further comprises a plurality of second bumps 464 disposed on the second active surface 432 of the second chip 430. The chip package structure 400a, 400b further comprise a plurality of solder balls 466 disposed on a rear surface of the substrate 410.

In the chip package structure 400a, 400b, the electrical connection between the first chip 420 and the substrate 410 is the same with the electrical connection between the first chip 220 and the substrate 210 (shown in FIG. 3A˜3D).

In an embodiment of the present invention, the chip package structure 400a, 400b further comprises a tape 480 disposed between the second chip 430 and the first chip 420. However, the tape 480 can be replace by an adhesive 482. In other words, the second chip 430 and the first chip 420 are adhered with each other by a solid adhesive or a liquid adhesive to ensure connection between the second chip 430 and the first chip 420.

It should be noted that the size of the second chip, illustrated in the first embodiment and the second embodiment of the present invention, is larger than that of the first chip. However, the size of the second chip may be equal to or smaller than that of the first chip. In an embodiment of the present invention, the encapsulant may be formed by single molding process. In other embodiment of the present invention, the encapsulant may be formed by two-step molding process. For example, a portion of the encapsulant is filled in the cavity of the substrate after the first chip is mounted in the cavity. Then, the other portion of the encapsulant is formed after the second chip and/or the third chip is mounted on the substrate. However, other molding process can also be utilized to form the encapsulant.

As described above, the present invention at least provides the following advantages.

In the chip package structure, since the chips are electrically connected to the substrate through bumps, the chip package structure has enhanced electrical performance.

Since the first contacts and the second contacts are located at different plane respectively, the risk of the short circuit between the wires, which electrically connect to different chips, is reduced.

Since the first contacts and the second contacts are located at different plane respectively, the length of the wires between the first chip and the second chip is reduced, such that the electrical performance is significantly enhanced.

Since the length of the wires between the first chip and the second chip is reduced, the curvature height of the wires is also reduced. Thus, the thickness of the chip package structure is further reduced.

Since the active surface of the third chip is exposed, a better heat dissipation characteristic is obtained.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to dedicate to the public regardless of whether the element or component is explicitly recited in the following claims.

1. A chip package structure, comprising:
a substrate having a cavity, wherein the substrate comprises a plurality of first contacts and second contacts disposed on a surface thereof, and the first contacts are located within the cavity and the second contacts are located outside the cavity;
a first chip disposed in the cavity, wherein the first chip is electrically connected to the first contacts;
a second chip disposed above the cavity, wherein the second chip is electrically connected to the second contacts; and
an encapsulant, wherein the encapsulant is filled in the cavity to encapsulate the first chip and the second chip.

2. The chip package structure of claim 1, further comprising a plurality of first bumps, wherein the first chip is electrically connected to the first contacts through the first bumps.

3. The chip package structure of claim 1, further comprising a plurality of second bumps, wherein the second chip is electrically connected to the second contacts through the second bumps.

4. The chip package structure of claim 1, further comprising a plurality of first wires, wherein the first chip is electrically connected to the first contacts through the first wires.

5. The chip package structure of claim 1, further comprising a plurality of second wires, wherein the second chip is electrically connected to the second contacts through the second wires.

6. The chip package structure of claim 1, further comprising a plurality of solder balls disposed on a rear surface of the substrate.

7. A chip package structure, comprising:
a substrate having a cavity, wherein the substrate comprises a plurality of first contacts and second contacts disposed on a surface thereof, and the first contacts are located within the cavity and the second contacts are located outside the cavity, the substrate further comprises a through hole located at the bottom of the cavity;
a first chip disposed in the cavity, wherein the first chip is electrically connected to the first contacts;
a second chip disposed above the cavity, wherein the second chip is electrically connected to the second contacts;
a third chip disposed in the through hole, wherein the third chip is attached to the first chip; and
an encapsulant, wherein the encapsulant is filled in the cavity to encapsulate the first chip and the second chip.

8. The chip package structure of claim 7, further comprising a plurality of first bumps, wherein the first chip is electrically connected to the first contacts through the first bumps.

9. The chip package structure of claim 7, further comprising a plurality of second bumps, wherein the second chip is electrically connected to the second contacts through the second bumps.

10. The chip package structure of claim 7, further comprising a plurality of first wires, wherein the first chip is electrically connected to the first contacts through the first wires.

11. The chip package structure of claim 7, further comprising a plurality of second wires, wherein the second chip is electrically connected to the second contacts through the second wires.

12. The chip package structure of claim 7, further comprising a plurality of third bumps and a plurality of solder balls, wherein the third bumps are disposed on a surface of the third chip away from the first chip, and the solder balls are disposed on a rear surface of the substrate.

13. The chip package structure of claim 7, further comprising a tape disposed between the third chip and the first chip.

14. The chip package structure of claim 7, further comprising an adhesive disposed between the third chip and the first chip.

15. A chip package structure, comprising:
a substrate having a cavity, wherein the substrate comprises a plurality of contacts disposed on a surface thereof, and the contacts are located within the cavity, the substrate further comprises a through hole located at the bottom of the cavity;
a first chip disposed in the cavity, wherein the first chip is electrically connected to the contacts;
a second chip disposed in the through hole, wherein the second chip is attached to the first chip; and
an encapsulant, wherein the encapsulant is filled in the cavity to encapsulate the first chip.

16. The chip package structure of claim 15, further comprising a plurality of first bumps, wherein the first chip is electrically connected to the contacts through the first bumps.

17. The chip package structure of claim 15, further comprising a plurality of wires, wherein the first chip is electrically connected to the contacts through the wires.

18. The chip package structure of claim 15, further comprising a plurality of second bumps and a plurality of solder balls, wherein the second bumps are disposed on a surface of the second chip away from the first chip, and the solder balls are disposed on a rear surface of the substrate.

19. The chip package structure of claim 15, further comprising a tape disposed between the second chip and the first chip.

20. The chip package structure of claim 15, further comprising an adhesive disposed between the second chip and the first chip.
